(19) United States
(12) Patent Application Publication
(10) Pub. No.: US 2019/0368040 A1
(43) Pub. Date: Dec. 5, 2019

(54) INFILTRATION APPARATUS AND METHODS OF INFILTRATING AN INFILTRATEABLE MATERIAL

(71) Applicant: ASM IP Holding B.V., Almere (NL)

(72) Inventors: Krzysztof Kamil Kachel, Heverlee (BE); Elina Färm, Helsinki (FI)

(21) Appl. No.: 15/996,286

(22) Filed: Jun. 1, 2018

(51) Int. Cl. C23C 16/455; H01L 21/027; H01L 21/02; C23C 16/56

(52) U.S. Cl. CPC C23C 16/45559; C23C 16/56; H01L 21/02211; H01L 21/0273

(57) ABSTRACT

An infiltration apparatus is disclosed. The infiltration apparatus may include: a reaction chamber constructed and arranged to hold at least a substrate provided with an infiltrateable material thereon; a first precursor source constructed and arranged to provide a vapor a first precursor comprising a silicon compound; a precursor distribution system and removal system constructed and arranged to provide the reaction chamber with the vapor of the first precursor from the first precursor source and to remove the vapor of the first precursor from the reaction chamber; and a sequence controller operably connected to the precursor distribution system and removal system and comprising a memory provided with a program to execute infiltration of the infiltrateable material when run on the sequence controller by; activating the precursor distribution system and removal system to provide the vapor of the first precursor to the infiltrateable material on the substrate in the reaction chamber whereby the infiltrateable material on the substrate in the reaction chamber is infiltrated with silicon atoms by the reaction of the vapor of the first precursor with the infiltrateable material. Methods of infiltration and semiconductor device structure including infiltrated materials are also provided.

### FIELD OF INVENTION

The present disclosure relates generally to an infiltration apparatus and particularly an infiltration apparatus configured for infiltrating an infiltrateable material with silicon atoms. The present disclosure also relates generally to methods of infiltrating an infiltrateable material.

### BACKGROUND OF THE DISCLOSURE

As semiconductor device structures trend towards smaller and smaller geometries, different patterning techniques have arisen. These techniques include self-aligned multiple patterning, spacer defined quadruple patterning, deep ultraviolet lithography (DUV), extreme ultraviolet lithography, and DUV/EUV combined with spacer defined double patterning. In addition, direct self-assembly (DSA) has been considered as an option for future lithography applications.

The patterning techniques described above may utilize at least one polymer resist disposed on a substrate to enable high resolution patterning of the substrate. To satisfy the requirements of both high resolution and low line-edge roughness, the polymer resist may commonly be a thin layer. However, such thin polymer resists may have several drawbacks. In particular, high resolution polymer resists may have a low etch resistance, i.e., high etch rates. This low etch resistance of the polymer resist makes the transfer of the patterned resist to the underlying layers more difficult. The issue of low etch resistance becomes greater when the advanced high resolution polymer resists need to be further downscaled as the polymer resist may have an even lower etch resistance and etch selectivity.

In some applications it may be advantageous to transfer the pattern of the polymer resist to a hardmask. A hardmask is a material used in semiconductor processing as an etch mask instead of, or in addition to, the polymer or other organic “soft” resist materials. Hardmask materials commonly have a higher etch resistance and higher etch selectivity than polymer resists. However, even a hardmask may have an etch rate which may need to be optimized.

Accordingly, polymer resists and hardmasks with advanced properties, such as, improved etch resistance, are desirable.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments an infiltration apparatus is disclosed. The infiltration apparatus may comprise a reaction chamber constructed and arranged to hold at least a substrate provided with an infiltrateable material thereon; a first precursor source constructed and arranged to provide a vapor of a first precursor comprising a silicon compound; a precursor distribution system and removal system constructed and arranged to provide the reaction chamber with the vapor of the first precursor from the first precursor source and to remove the vapor of the first precursor from the reaction chamber; and a sequence controller operably connected to the precursor distribution system and the removal system and comprising a memory provided with a program to execute infiltration of the infiltrateable material when run on the sequence controller by; activating the precursor distribution and removal system to provide the vapor of the first precursor to the infiltrateable material on the substrate in the reaction chamber whereby the infiltrateable material on the substrate in the reaction chamber is infiltrated with silicon atoms by the reaction of the vapor of the first precursor with the infiltrateable materials.

In some embodiments a method of infiltrating an infiltrateable material is provided. The method may comprise providing a substrate with the infiltrateable material disposed thereon in a reaction chamber; providing a first precursor comprising a silicon compound to the infiltrateable material in the reaction chamber for a first time period (T₁) whereby the infiltrateable material on the substrate in the reaction chamber is infiltrated with silicon atoms; and purging the reaction chamber for a second time period (T₂).

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a non-limiting exemplary infiltration apparatus according to the embodiments of the disclosure;

FIG. 2 illustrates a non-limiting exemplary process flow, demonstrating a method for infiltrating an infiltrateable material employing a first precursor according to the embodiments of the disclosure;

FIG. 3 illustrates an additional non-limiting exemplary process flow, demonstrating a method for infiltrating an infiltrateable material employing a first precursor and a second precursor according to the embodiments of the disclosure;

FIG. 4 illustrates a non-limiting exemplary process flow, demonstrating a method for sequential infiltration synthesis (SIS) according to the embodiments of the disclosure;

FIG. 5 illustrates an additional non-limiting exemplary flow, demonstrating an additional method for sequential infiltration synthesis (SIS) according to the embodiments of the disclosure;

FIG. 6 represents a x-ray photoelectron spectrum (XPS) obtained from an infiltrated material according to the embodiments of the disclosure;

FIG. 7 represents a secondary ion mass spectrum (SIMS) obtained from an infiltrated material according to the embodiments of the disclosure; and

FIG. 8 illustrates a schematic cross-sectional view of a semiconductor device structure including an infiltrated material according to the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “substrate” may refer to any underlying material or materials that may be used, or upon which, a device, a circuit, or a film may be formed.

As used herein, the term “infiltrateable material” may refer to any material into which an additional species, such as atoms, molecules, or ions, may be introduced.

As used herein, the term “semiconductor device structure” may refer to any portion of a processed, or partially processed, semiconductor structure that is, includes, or defines at least a portion of an active or passive component of a semiconductor device to be formed on or in a semiconductor substrate. For example, semiconductor device structures may include, active and passive components of integrated circuits, such as, for example, transistors, memory elements, transducers, capacitors, resistors, conductive lines, conductive vias, and conductive contact pads.

A number of example materials are given throughout the embodiments of the current disclosure, it should be noted that the chemical formulas given for each of the example materials should not be construed as limiting and that the non-limiting example materials given should not be limited by a given example stoichiometry.

The present disclosure includes infiltration apparatus and infiltration methods that may be utilized to increase the etch resistance of materials, such as, for example, polymer resists and hardmask materials, employed as etch masks in semiconductor device fabrication processes.

Infiltration processes, such as, for example, sequential infiltration synthesis (SIS), have been demonstrated to increase the etch resistance of various organic materials by modifying the organic material with an inorganic protective component. For example, the SIS process utilizes alternating exposures of the polymer resist to gas phase precursors that infiltrate the organic resist material to form a protective component within the resist layer. The SIS process and its uses are described in U.S. Patent App. 2012/0241411, and incorporated by reference herein. Therefore, combining infiltration processes with high resolution polymer resists and hardmask patterning may provide benefits previously unseen with prior approaches, such as the one described in U.S. Patent App. 2014/0273514.

Prior infiltration processes commonly involve the infiltration of a metal oxide, such as, for example, aluminum oxide (Al₂O₃) into a high resolution polymer resist. For example, alternating pulses of trimethylaluminum (TMA) and water (H₂O) at a substrate temperature of 90° C. may allow infiltration of aluminum oxide within a high resolution polymer resist disposed on a substrate. However, in some semiconductor device applications, it may be undesirable to utilize a metal oxide as the infiltrating material. For example, the use of aluminum oxide as the infiltrating material may result in unwanted memory effects in plasma etching apparatus and in addition the remaining aluminum oxide may be difficult to remove. Accordingly, infiltration apparatus and processes are desirable that may infiltrate alternative materials/species into high resolution polymer resists and hardmask materials.

Therefore, in some embodiments of the disclosure, an infiltration apparatus may be disclosed. In some embodiments, the infiltration apparatus may comprise: a reaction chamber constructed and arranged to hold at least a substrate provided with an infiltrateable material thereon; a first precursor source constructed and arranged to provide a vapor of a first precursor comprising a silicon compound; a precursor distribution system and a removal system constructed and arranged to provide the reaction chamber with the vapor of the first precursor from the first precursor source and to remove the vapor of the first precursor from the reaction chamber; and a sequence controller operably connected to the precursor distribution system and the removal system and comprising a memory provided with a program to execute infiltration of the infiltrateable material when run on the sequence controller by; activating the precursor distribution system and the removal system to provide the vapor of the first precursor to the infiltrateable material on the substrate in the reaction chamber whereby the infiltrateable material on the substrate in the reaction chamber is infiltrated with silicon atoms by the reaction of the vapor of the first precursor with the infiltrateable material.

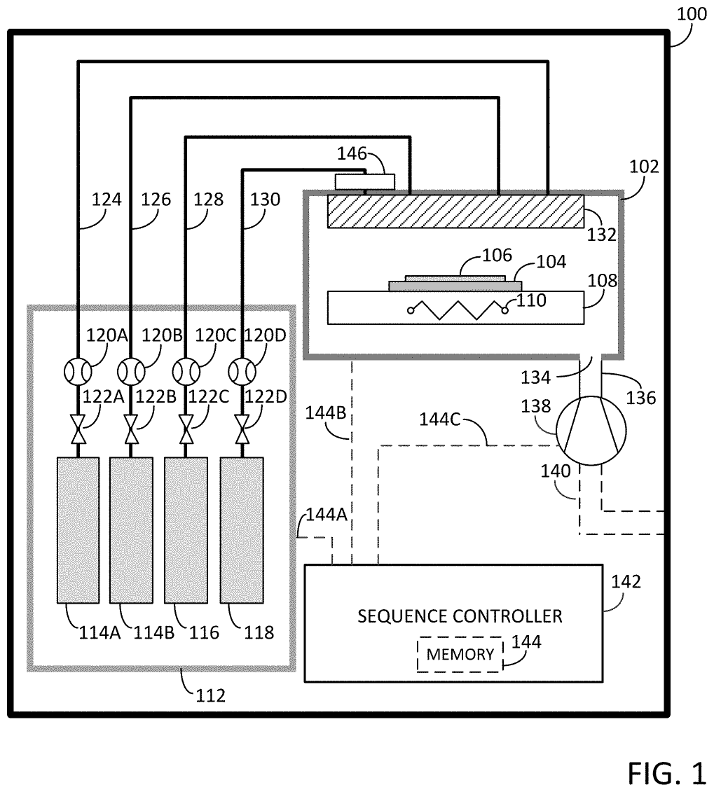

A non-limiting example of an infiltration apparatus of the current disclosure is illustrated in FIG. 1 which comprises a schematic diagram of an exemplary infiltration apparatus 100 according to the embodiments of the disclosure. It should be noted that the infiltration apparatus 100 illustrated in FIG. 1 is a simplified schematic version of the exemplary infiltration apparatus and does not contain each and every element, i.e., such as each and every valve, gas line, heating element, and reactor component, etc., that may be utilized in the fabrication of the infiltration apparatus of the current disclosure. The infiltration apparatus as illustrated in FIG. 1 provides the key features of the infiltration apparatus to provide sufficient disclosure to one of ordinary skill in the art to appreciate the embodiments of the current disclosure.

The exemplary infiltration apparatus 100 may comprise a reaction chamber 102 constructed and arranged to hold at least a substrate 104 provided with an infiltrateable material 106 thereon.

Reaction chambers capable of being used to infiltrate an infiltrateable material can be used for the infiltration processes described herein. Such reaction chambers may include reaction chambers configured for atomic layer deposition (ALD) processes, as well as reaction chambers configured for chemical vapor deposition (CVD) processes. According to some embodiments, a showerhead reaction chamber may be used. According to some embodiments, cross-flow, batch, minibatch, or spatial ALD reaction chambers may be used.

In some embodiments of the disclosure, a batch reaction chamber may be used. In some embodiments, a vertical batch reaction chamber may be used. In other embodiments, a batch reaction chamber comprises a minibatch reactor configured to accommodate 10 or fewer wafers, 8 or fewer wafers, 6 or fewer wafers, 4 or fewer wafers, or 2 or fewer wafers.

The infiltration processes described herein may optionally be carried out in a reactor or reaction chamber connected to a cluster tool. In a cluster tool, because each reaction chamber is dedicated to one type of process, the temperature of the reaction chamber in each module can be kept constant, which improves the throughput compared to a reactor in which the substrate is heated up to the process temperature before each run. Additionally, in a cluster tool it is possible to reduce the time to pump the reaction chamber to the desired process pressure levels between substrates. In some embodiments of the disclosure, both an infiltration process and an etch process may be performed in a cluster tool comprising multiple reaction chambers, wherein each individual reaction chamber may be utilized to expose the substrate to an individual precursor gas/plasma chemistry and the substrate may be transferred between different reaction chambers for exposure to multiple precursor gasses and/or plasma chemistries, the transfer of the substrate being performed under a controlled ambient to prevent oxidation/contamination of the substrate. In some embodiments of the disclosure, the infiltration processes and etch processes may be performed in a cluster tool comprising multiple reaction chambers, wherein each individual reaction chamber may be configured to heat the substrate to a different temperature.

A stand-alone infiltration apparatus may be utilized including a reaction chamber that may be constructed and arranged to solely perform infiltration processes and may be equipped with a load-lock. In that case, it is not necessary to cool down the reaction chamber between each run.

Disposed within the reaction chamber 102 may be at least one substrate 104 with an infiltrateable material 106 disposed thereon, i.e., disposed on an upper surface of the substrate 104. In some embodiments of the disclosure, the substrate 104 may comprise a planar substrate (as illustrated in FIG. 1) or a patterned substrate. The substrate 104 may comprise one or more materials including, but not limited to, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some embodiments of the disclosure, the substrate 104 may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides or nitrides, such as, for example, silicon oxides and silicon nitrides.

In some embodiments of the disclosure, the substrate 104 has an infiltrateable material 106 disposed thereon, i.e., disposed on an upper surface of the substrate 104. The infiltrateable material 106 may comprise any material into which an additional species may be introduced which, when introduced into the infiltrateable material 106, may increase the etch resistance of the infiltrateable material 106. In some embodiments of the disclosure the infiltrateable material 106 may comprise at least one of a polymer resist, such as, for example, a photoresist, an extreme ultraviolet (EUV) resist, an immersion photoresist, a chemically amplified resist (CAR), or an electron beam resist (e.g., poly(methyl methacrylate) (PMMA)). In some embodiments of the disclosure the infiltrateable material 106 may comprise a porous material, e.g., micro-porous and/or nano-porous, including porous materials such as, for example, spin-on-glasses (SOG), and spin-on-carbon (SOC). In some embodiments of the disclosure the infiltrateable material 106 may comprise one or more hardmask materials, including, but not limited to, silicon oxides, silicon nitrides, and silicon oxynitrides.

The infiltrateable material 106 may comprise a patterned infiltrateable material which comprises one or more infiltrateable features which may be transferred during a subsequent etching process into the underlying substrate. The infiltrateable features may comprise any geometry that may be formed depending on the exposure and associated development processes and may include, but is not limited to, line features, block features, open pore features, and circular features.

The substrate 104 may be disposed in the reaction chamber 102 and held in position by a susceptor 108 configured to retain at least one substrate thereon. In some embodiments of the disclosure, the infiltration processes disclosed herein may utilize processes which heat the substrate 104 and the associated infiltrateable material 106 to a suitable process temperature. Therefore, the susceptor 108 may comprise one or more heating elements 110 which may be configured to heat the substrate 104 with the infiltrateable material 106 disposed thereon to a temperature of greater than approximately 0° C., or greater than approximately 100° C., or greater than approximately 200° C., or greater than approximately 300° C., or greater than approximately 400° C., or even greater than approximately 450° C.

In some embodiments of the disclosure, the exemplary infiltration apparatus 100 may comprise, a gas delivery system 112 which may further comprise one or more precursor sources 114A and 114B constructed and arranged to provide a vapor of a number of precursors and dispense the associated vapors to the reaction chamber 102. The gas delivery system 112 may also comprise a source vessel 116 configured for storing and dispensing a purge gas that may be utilized in a purge cycle of the exemplary infiltration processes described herein. The gas delivery system 112 may also comprise a reactant source vessel 118 configured for containing and dispensing a reactant to the reaction chamber 102 to be utilized in an exemplary infiltration process described herein. As a non-limiting example, the infiltration apparatus 100 may include a first precursor source 114A constructed and arranged to provide a vapor of a first precursor comprising a silicon compound. In some embodiments, the first precursor source 114A may comprise a first precursor evaporator constructed and arranged to evaporate a first precursor comprising a silicon compound.

In some embodiments, the first precursor source 114A may comprise a source vessel configured for storing and containing a first precursor under suitable operating conditions. For example, the first precursor may comprise a solid precursor, a liquid precursor, or a vapor phase precursor, and the source vessel may be configured for storing and containing the solid, liquid, or vapor phase precursor under suitable operating conditions. In some embodiments, the first precursor may comprise a silicon compound in liquid form and the first precursor source may comprise a first precursor evaporator which may include one or more controllable heating elements which may heat the first precursor to a suitable operating temperature to thereby controllably evaporate a portion of the first precursor, the evaporated vapor subsequently being distributed to the reaction chamber 102 via suitable means to infiltrate the infiltrateable material. In some embodiments, the one or more heating elements associated with the first precursor source 114A may be configured to control the vapor pressure of the first precursor. In addition, a flow controller 120A, such as for, example a mass flow controller (MFC), may be further associated with the first precursor source 114A and may be configured to control the mass flow of the vapor produced from the first precursor source 114A, such as, for example, the first precursor evaporator. In addition to the flow controller 120A, a valve 122A, e.g., a shut-off valve, may be associated with the first precursor source 114A and may be utilized to disengage the first precursor source 114A from the reaction chamber 102, i.e., when the valve 122A is in the closed position vapor produced by the first precursor source 114A may be prevented from flowing into the reaction chamber 102.

In additional embodiments, the first precursor source 114A may further comprise a carrier gas input (not shown) such that a carrier gas (e.g., nitrogen) may be passed over or bubbled through the first precursor such that the first precursor may become entrained in the carrier gas and the carrier gas/first precursor vapor may be subsequently delivered to the reaction chamber 102 by appropriate means.

In some embodiments the first precursor source 114A may be constructed and arranged to provide a vapor of a first precursor comprising a silicon compound. For example, the first precursor source 114A may comprise a first precursor evaporator constructed and arranged to evaporate a portion of the first precursor thereby producing a vapor of the first precursor comprising a silicon compound. In some embodiments, the first precursor source 114A may be constructed and arranged to provide a vapor of a substituted silane In some embodiments, the first precursor source 114A may be constructed and arranged to provide a vapor of an aminosilane. In some embodiments, the first precursor source may be constructed and arranged to provide a vapor of a 3-aminopropyl and silicon comprising compound, i.e., a silicon precursor comprising both a 3-aminopropyl component and a silicon component.

In some embodiments, the first precursor source 114A may be constructed and arranged to provide a vapor of 3-aminopropyl triethyoxysilane (APTES). For example, the first precursor source 114A may comprise a first precursor evaporator which may be constructed and arranged to evaporate 3-aminopropyl triethyoxysilane (APTES). For example, APTES may be stored and contained in a suitable source vessel and associated heating elements may be utilized to heat the APTES to a temperature of greater than 0° C., or greater than 90° C., or even greater than 230° C., in order to vaporize a portion of the APTES thereby producing a vaporized first precursor suitable for infiltrating an infiltrateable material.

In some embodiments, the first precursor source 114A may be constructed and arranged to provide a vapor of 3-aminopropyl-trimethoxysilane (APTMS). For example, the first precursor source 114A may comprise a first precursor evaporator which may be constructed and arranged to evaporate 3-aminopropyl-trimethoxysilane (APTMS). For example, APTMS may be stored and contained in a suitable source vessel and associated heating elements may be utilized to heat the APTMS to a temperature of greater than 0° C., or greater than 90° C., or even greater than 230° C., in order to vaporize a portion of the APTES thereby producing a vaporized first precursor suitable for infiltrating an infiltrateable material.

In some embodiments of the disclosure the first precursor source 114A may be constructed and arrange to provide a vapor of a silicon precursor comprising an alkoxide ligand and an additional ligand other than an alkoxide ligand. For example, the first precursor source 114A may comprise a first precursor evaporator which may be constructed and arranged to evaporate a silicon precursor comprising an alkoxide ligand and an additional ligand other than an alkoxide ligand.

In some embodiments, the first precursor source 114A may be constructed and arranged to provide a vapor of a silicon precursor comprising an amino-substituted alkyl-group attached to a silicon atom. As non-limiting example embodiments of the disclosure, the first precursor source 114, e.g., a first precursor evaporator, may be constructed and arranged to provide a vapor of a silicon precursor having the general formulae (I)-(III);

A-R⁰—Si-L¹-L²-L³ (I)

A-R⁰—Si—(OR¹)(OR²)(OR³) (II)

H₂N—R—Si—(OR¹)(OR²)(OR³) (III)

wherein A is substituent for a carbon chain such as, for example, NH₂, NHR, NR2, or OR, and R is a carbon chain backbone, such as, for example, C1-C5 alkyl groups, and L is NR2 (alkylamine), alkoxide (OR), a halogen, or hydrogen.

In some embodiments of the disclosure the first precursor source 114A may be constructed and arranged to provide a vapor of a silicon compound comprising a halide, such as, for example, a silicon halide, a halogenated silane, or a silane comprising a halide. In some embodiments the silicon compound comprises a chloride, such as, for example, at least one of hexachlorodisilane (HCDS), dichlorosilane (DCS), or silicon tetrachloride (SiCl₄). As non-limiting example embodiments of the disclosure, the first precursor source 114A may be constructed and arranged to provide a vapor a silicon precursor having the general formulae (IV)-(VI);

SiₙX₂ₙ₊₂ (where n is from 1 to 4) (IV)

SiₙX_{2n+2-w}L_{w} (wherein n is from 1 to 4, w is from 0 to 4) (V)

SiₙX_{2n+2-w-y}L_{w}H_{y} (wherein n is from 1 to 4, w is from 0 to 4-y, y is from 0 to 4-w) (VI)

wherein X is a halogen, such as fluorine (F), chlorine (Cl), bromine (Br), or iodine (I), and L is NR2 (alkylamine), alkoxide (OR), halogen, or hydrogen, and H is hydrogen.

In some embodiments of the disclosure, the first silicon precursor may already be in a vapor state when stored in a suitable source vessel and the precursor source may be utilized to control the vapor pressure of the vapor phase silicon precursor by raising and lowering the temperature of the vapor phase silicon precursor in the associated source vessel. Therefore, it should be appreciated that the precursor sources of the disclosure may be utilized to contain and dispense vapor phase reactants, as well as solid, liquid, or mixed phase reactants.

In some embodiments of the disclosure, the exemplary infiltration apparatus 100 (FIG. 1) may comprise a precursor distribution and removal system constructed and arranged to provide the reaction chamber 102 with a vapor of the first precursor from the first precursor source 114A and to remove the vapor of the first precursor from the reaction chamber 102.

In more detail, the precursor distribution system may comprise gas delivery system 112, and one or more gas lines, such as, for example, gas line 124 in fluid communication with first precursor source 114A, gas line 126 in fluid communication with second precursor source 114B, gas line 128 in fluid communication with source vessel 116, and gas line 130 in fluid communication with reactant source vessel 118. As a non-limiting example, gas line 124 is fluidly connected to the first precursor source 114A and may be configured for conveying a vapor of the first precursor to the reaction chamber 102.

The precursor distribution system may further comprise a gas dispenser 132 configured for dispensing the vapor of the first precursor into reaction chamber 102 and over the substrate 104 with the infiltrateable material 106 disposed thereon, the gas dispenser 132 being in fluid communication with gas line 124, in addition to being in fluid communication with gas lines 126, 128, and 130.

As a non-limit example embodiment, the gas dispenser 132 may comprise a showerhead as illustrated in block form in FIG. 1. It should be noted that although the showerhead is illustrated in block form, the showerhead may be a relatively complex structure. In some embodiments, the showerhead may be configured to mix vapors from multiple sources prior to distributing a gas mixture to the reaction chamber 102. In alternative embodiments, the showerhead may be configured to maintain separation between multiple vapors introduced into the showerhead, the multiple vapors only coming into contact with one another in the vicinity of the substrate 104 disposed within the reaction chamber 102. Further, the showerhead may be configured to provide vertical or horizontal flow of gas into the reaction chamber 102. An exemplary gas distributor is described in U.S. Pat. No. 8,152,922, the contents of which are hereby incorporated herein by reference, to the extent such contents do not conflict with the present disclosure.

As illustrated in FIG. 1 the precursor distribution system may comprise gas delivery system 112, at least gas lines 124, 126, 128 and 130, and a gas distributor 132, however it should be noted that the precursor distribution system may include additional components not illustrated in FIG. 1, such as, for example, additional gas lines, valves, actuators, seals, and heating elements.

In addition to the precursor distribution system, the exemplary infiltration apparatus 100 may also comprise a removal system constructed and arranged to remove gasses from the reaction chamber 102. In some embodiments, the removal system may comprise an exhaust port 134 disposed within a wall of reaction chamber 102, an exhaust line 136 in fluid communication with exhaust port 134, and a vacuum pump 138 in fluid communication with the exhaust line 136 and configured for evacuating gasses from within reaction chamber 102. Once the gas or gasses have been exhausted from the reaction chamber 102 utilizing vacuum pump 138 they may be conveyed along additional exhaust line 140 and exit the exemplary infiltration apparatus 100 where they may undergo further abatement processes.

To further assist in the removal of precursor gasses, i.e., reactive vapors, from within reaction chamber 102, the removal system may further comprise a source vessel 116 fluidly connected through a gas line 128 to a gas distributor 132. For example, the source vessel 116 may be configured for containing and storing a purge gas, such as, for example, argon (Ar), nitrogen (N₂), or helium (He). A flow controller 120C and valve 122C associated with the source vessel 116 may control the flow and particularly the mass flow of purge gas conveyed through gas line 128 to gas distributor 132 and into reaction chamber 102 wherein the purge gas may assist in the removal of vapor phase precursor gases, inert gasses, and byproducts from within reaction chamber 102 and particularly purge precursor gas and unreacted byproducts from an exposed surface of infiltrateable material 106. The purge gas (and any associated precursor and byproducts) may exit the reaction chamber 102 via exhaust port 134 through the utilization of vacuum pump 138.

In some embodiments of the disclosure the exemplary infiltration apparatus 100 may further comprise, a sequence controller operably connected to the precursor distribution system and the removal system and comprising a memory provided with a program to execute infiltration of the infiltrateable material when run on the sequence controller.

In more detail, the exemplary infiltration apparatus 100 may comprise a sequence controller 142 which may also comprise control lines 144A, 144B, and 144C, wherein the control lines may interface various systems and/or components of the infiltration system 100 to the sequence controller 142. For example, control line 144A may interface the sequence controller 142 with gas delivery system 112 and thereby provide control to the precursor distribution system including gas lines 124, 126, 128 and 130, as well as gas distributor 132. The control line 144B may interface the sequence controller 142 with the reaction chamber 102 thereby providing control over operation of the reaction chamber, including, but not limited to, process pressure and susceptor temperature. The control line 144C may interface the sequence controller 142 with the vacuum pump 138 such that operation and control over the gas removal system may be provided by sequence controller 142.

It should be noted that as illustrated in FIG. 1 the sequence controller 142 includes three control lines 144A, 144B, and 144C, however it should be appreciated a multitude of control lines, i.e., electrically and/or optically connected control lines, may be utilized to interface the desired systems and components comprising infiltration apparatus 100 with the sequence controller 142 thereby providing overall control over the infiltration apparatus 100.

In some embodiments of the disclosure, the sequence controller 142 may comprise electronic circuitry to selectively operate valves, heaters, flow controllers, manifolds, pumps and other equipment included in the exemplary infiltration apparatus 100. Such circuitry and components operate to introduce precursor gasses and purge gasses from respective precursor sources 114A, 114B, reactant source vessel 118 and purge gas source vessel 116. The sequence controller 142 may also control the timing of precursor pulse sequences, temperature of the substrate and reaction chamber, and the pressure of the reaction chamber and various other operations necessary to provide proper operation of the infiltration apparatus 100. In some embodiments, the sequence controller 142 may also comprise control software and electrically or pneumatically controlled valves to control the flow of precursors and purge gasses into and out of the reaction chamber 102. In some embodiments of the disclosure the sequence controller 142 may comprise a memory 144 provided with a program to execute infiltration of the infiltrateable material when run on the sequence controller. For example, the sequence controller 142 may include modules such as software or hardware components, such as, for example, a FPGA or ASIC, which performs certain infiltration processes. A module can be configured to reside on an addressable storage medium of the sequence controller 142 and may be configured to execute one or more infiltration processes.

In some embodiments of the disclosure, the memory 144 of sequence controller 142 may be provided with a program to execute infiltration of the infiltrateable material 106 when run on the sequence controller 142 by; activating the precursor distribution system and removal system to provide the vapor of the first precursor to the infiltrateable material 106 on the substrate 104 within the reaction chamber 102 whereby the infiltrateable material 106 on the substrate 104 within the reaction chamber 102 is infiltrated with silicon atoms by the reaction of the vapor of the first precursor with the infiltrateable material 106.

In some embodiments of the disclosure the exemplary infiltration apparatus 100 may comprise a second precursor source 114B, such as, for example, a second precursor evaporator. In more detail, the second precursor source 114B may be constructed and arranged to provide a vapor of a second precursor comprising a silicon compound. For example, the second precursor source 114B may comprise a second precursor evaporator that may be constructed and arranged to evaporate a second precursor comprising a silicon compound. In some embodiments, the second precursor source 114B may be identical, or substantially identical, to the first precursor source 114A and therefore details regarding the second precursor source 114B are omitted for brevity.

In some embodiments, the precursor distribution system and removal system may be constructed and arranged to provide the reaction chamber 102 with a vapor of the second precursor from the second precursor source 114B. For example, gas line 126 may be fluidly connected to the second precursor source 114B via flow controller 120B and valve 122B, and may convey the vapor of the second precursor from the second precursor source 114B to gas distributor 132 and subsequently into the reaction chamber 102. In some embodiments, the program in the memory 144 may be programmed to execute infiltration of the infiltrateable material 106 when run on the sequence controller 142 by; activating the precursor distribution system and the removal system to provide the vapor of the second precursor to the reaction chamber 102 whereby the infiltrateable material 106 on the substrate 104 may be infiltrated with silicon atoms from the vapor of the second precursor.

In some embodiments of the disclosure, the second precursor source 114B may be constructed and arranged to provide a vapor of any of the silicon precursors, i.e., silicon containing compounds, as previously described herein with reference to the first precursor source 114A. In some embodiments, the second precursor source 114B may be constructed and arranged to provide a vapor of a different silicon compound than the first precursor source 114A, in other words the second precursor source 114B may be constructed and arranged to provide a vapor of a second silicon precursor which may be different to the vapor of the first silicon precursor provided by the first precursor source 114A. As a non-limiting example, the first precursor source 114A may be constructed and arranged to evaporate APTES and provide a vapor of APTES to the reaction chamber 102 and the second precursor source 114B may be constructed and arranged to evaporate HCDS and provide a vapor of HCDS to the reaction chamber 102.

In some embodiments of the disclosure, the program in the memory 144 may be programmed to execute the infiltration of the infiltrateable material 106 when run on the sequence controller 142 by; activating the precursor distribution system and the removal system to provide the second precursor simultaneously with the first precursor, i.e., both the first precursor source 114A and the second precursor source 114B may simultaneously provide a vapor of the second precursor and a vapor of the first precursor into the reaction chamber 102 such that the infiltrateable material 106 disposed on the substrate 104 may be infiltrated simultaneously by both the vapor of the second precursor, i.e., the second silicon compound, and the vapor of the first precursor, i.e., the first silicon compound.

In some embodiments of the disclosure, the program in the memory 144 may be programmed to execute infiltration of the infiltrateable material 106 when run on the sequence controller 142 by; activating the precursor distribution system and removal system to provide the second precursor after the first precursor, i.e., the first precursor source 114A may provide a vapor of the first precursor into the reaction chamber 102 and infiltrate the infiltrateable material 106 with the first precursor and subsequently the second precursor source 114B may provide a vapor of the second precursor to the reaction chamber 102 and infiltrate the infiltrateable material 106 with the second precursor.

In some embodiment, the sequence controller 142 may run a program on the memory 144 in order to activate the precursor distribution system and the removal system to provide the first precursor after the second precursor, i.e., the second precursor source 114B may provide a vapor of the second precursor to the reaction chamber 102 to infiltrate the infiltrateable material 106 with the second precursor vapor and subsequently the first precursor source 114A may provide a vapor of the first precursor to the reaction chamber 102 to infiltrate the infiltrateable material 106 with the first precursor vapor.

In some embodiments of the disclosure, the program mounted in the memory 144 may be programmed to execute infiltration of the infiltrateable material 106 when run on the sequence controller 142 by; activating the precursor distribution system and removal system to provide the first precursor to the reaction chamber 102, followed by a purge cycle to remove excess first precursor and any byproducts from the reaction chamber, and subsequently provide the second precursor to the reaction chamber, followed by a second purge cycle to remove excess second precursor and any byproducts from the reaction chamber.

In more detail, a program mounted within the memory 144 of sequence controller 142 may first activate the first precursor source 114A and provide a vapor of the first precursor to the reaction chamber 102 to infiltrate the infiltrateable material 106 with the vapor of the first precursor, subsequently the first precursor source 114A may be deactivated and the fluid connection to the reaction chamber 102 between the first precursor source 114A and the reaction chamber 102 may be disengaged, e.g., by the valve 122A associated with the first precursor source 114A. Once the first precursor source 114A is deactivated and disengaged from the reaction chamber 102 the program mounted in the memory 144 of sequence controller 142 may engage, or continue to engage, the vacuum pump 138 to exhaust excess vapor of the first precursor and any byproducts from the reaction chamber 102. In additional embodiments, in addition to utilizing the vacuum pump 138 to exhaust excess vapor of the first precursor and any byproducts from the reaction chamber 102, the program mounted in memory 144 of sequence controller 142 may activate source vessel 116 containing a source of purge gas, e.g., by opening the valve 122C associated the source vessel 116. The purge gas may flow through gas line 128 and into reaction chamber 102 via gas distributor 132 and purge the reaction chamber 102 and in particularly may purge the infiltrateable material 106 disposed upon substrate 104. The program mounted in memory 144 of sequence controller 142 may subsequently deactivate the flow of purge gas through the reaction chamber 102 and subsequently activate the second precursor source 114B to thereby provide a vapor of the second precursor to the reaction chamber 102 and particular to infiltrate the infiltrateable material 106 with the second precursor vapor provided by the second vapor source 114B. The program mounted in memory 144 of sequence controller 142 may subsequent deactivate the flow of the vapor of the second precursor to the reaction chamber 102 and subsequently activate the source vessel 116 to again purge the reaction chamber, e.g., remove excess vapor of the second precursor.

In some embodiments of the disclosure, the program mounted in the memory 144 may be programmed to execute infiltration of the infiltrateable material 106 when run on the sequence controller 142 by; activating the precursor distribution system and removal system to provide the vapor of the second precursor to the reaction chamber, followed by a purge cycle to remove excess vapor of the second precursor and any byproducts from the reaction chamber, subsequently provide the vapor of the first precursor to the reaction chamber, followed by a purge cycle to remove excess vapor of the first precursor and any byproducts from the reaction chamber.

In additional embodiments of the disclosure, the exemplary infiltration apparatus 100 may comprise a sequential infiltration synthesis (SIS) apparatus. For example, a sequential infiltration synthesis (SIS) apparatus may be constructed and arranged to provide alternating, self-limiting exposures of the infiltrateable material to two or more vapor phase precursors. Therefore, in addition to the first precursor source 114A and the second precursor source 114B, the exemplary infiltration apparatus 100 may further comprise a reactant source vessel 118 and a reactant supply line, i.e., gas line 130, constructed and arranged to provide a reactant comprising an oxygen precursor to the reaction chamber 102.

In some embodiments of the disclosure, reactant source vessel 118 may comprise a reactant in the solid phase, in the liquid phase, or in the vapor phase. In some embodiments, the reactant source vessel 118 may comprise a reactant evaporator, i.e., one or more heating elements may be associated with the reactant source vessel to enable evaporation of the reactant and thereby provide a vaporized reactant comprising an oxygen precursor to the reaction chamber 102. In some embodiments, the control of the flow of the vapor reactant comprising an oxygen precursor to the reaction chamber may be achieved through the use of the valve 122D and flow controller 120D both associated with the reactant source vessel 118. In some embodiments of the disclosure wherein the reactant source vessel 118 further comprises a reactant evaporator, the reactant evaporator may be constructed and arranged to evaporate at least one of water (H₂O), or hydrogen peroxide (H₂O₂) as the reactant comprising an oxygen precursor.

In some embodiments of the disclosure, the reactant source vessel 118 may store and dispense a gaseous oxygen precursor to the reaction chamber 102 via reactant supply line 130 and gas distributor 132. In some embodiments, the gaseous oxygen precursor may comprise at least one of ozone (O₃), or molecular oxygen (O₂).

In some embodiments of the disclosure, the exemplary infiltration apparatus 100 may optionally further comprise a plasma generator 146 constructed and arranged to generate a plasma from the gaseous oxygen precursor thereby providing one or more of atomic oxygen, oxygen ions, oxygen radicals, and excited species of oxygen to the reaction chamber 102 whereby the oxygen based plasma produced by the plasma generator 146 may react with the infiltrateable material 106 disposed over substrate 104.

In some embodiments of the disclosure, the exemplary infiltration apparatus 100 may be a sequential infiltration synthesis apparatus further comprising: a reactant source vessel 118 and a reactant supply line 130 constructed and arranged to provide a reactant comprising an oxygen precursor to the reaction chamber 102, wherein the program in the memory 144 of the sequence controller 142 may be programmed to execute infiltration of the infiltrateable material 106 when run on the sequence controller 142 by activating the precursor distribution system and the removal system to remove gas from the reaction chamber 102, and activating the precursor distribution system and the removal system to provide the reactant comprising an oxygen precursor to the reaction chamber 102 whereby the infiltrateable material 106 on the substrate 104 in the reaction chamber 102 is infiltrated with silicon atoms and oxygen atoms by the reaction of the first precursor and the reactant comprising the oxygen precursor with the infiltrateable material 106. In some embodiments the program sequence of providing the first precursor, and subsequently providing the reactant may be repeated one or more times. In some embodiments each step in the program sequence may be followed by a purge cycle to remove excess precursor and byproducts from the reaction chamber by exhausting the reaction chamber 102 utilizing vacuum pump 138 and optionally flowing a purge gas from source vessel 116.

In some embodiments of the disclosure, the program mounted in the memory 114 may be programmed to execute sequential infiltration synthesis of the infiltrateable material 106 when run on the sequence controller 142 by; activating the precursor distribution system and removal system to provide the oxygen precursor to the reaction chamber from reactant source vessel 118, followed by the vapor of the first precursor from the first precursor source 114A to the reaction chamber 102, to thereby infiltrate the infiltrateable material with both silicon and oxygen atoms. In some embodiments, the program sequence of providing the oxygen precursor followed by the vapor of the first precursor may be repeated one or more times. In some embodiments, each step in the program sequence may be followed by a purge cycle to remove excess precursor and byproducts from the reaction chamber by exhausting the reaction chamber 102 utilizing the vacuum pump 138 and optionally flowing a purge gas from source vessel 116.

In some embodiments of the disclosure, the apparatus comprises a sequential infiltration synthesis apparatus and further comprises a second precursor source 114B constructed and arranged to provide a vapor of the second precursor to the reaction chamber 102. For example, the second precursor source 114B may comprise a second precursor evaporator constructed and arranged to evaporate a second precursor comprising a silicon compound. In some embodiments, the precursor distribution system and the removal system may be constructed and arranged to provide the reaction chamber 102 with the vapor of the second precursor from the second precursor source 114B and the program in the memory 144 is programmed to execute infiltration of the infiltrateable material when run on the sequence controller 142 by; activating the precursor distribution system and the removal system to provide the second precursor.

In some embodiments of the disclosure, the program in the memory 144 is programmed to execute infiltration of the infiltrateable material 106 when run on the sequence controller 142 by: activating the precursor distribution system and the removal system to provide the first precursor, subsequently the reactant, subsequently the second precursor, and subsequently the reactant.

In some embodiments of the disclosure, the program in memory 144 may be programmed to execute infiltration of the infiltrateable material 106 when run on the sequence controller 142 by: activating the precursor distribution system and removal system to repeat providing the first precursor, subsequently the reactant, subsequently the second precursor, and subsequently the reactant multiple times.

In some embodiments of the disclosure, the program in memory 144 may be programmed to execute infiltration of the infiltrateable material 106 when run on the sequence controller 142 by: activating the precursor distribution system and the removal system to remove the precursors and/or reactants from the reaction chamber in between each step of providing the first precursor, subsequently the reactant, subsequently the second precursor, and subsequently the reactant.

In some embodiments of the disclosure, the program in memory 144 may be programmed to execute infiltration of the infiltrateable material 106 when run on the sequence controller 142 by: activating the precursor distribution system and the removal system to provide the first precursor, subsequently provide the second precursor, and subsequently provide the reactant. In some embodiments the program sequence of providing the first precursor, subsequently providing the second precursor, and subsequently providing the reactant may be repeated one or more times. In some embodiments each step in the program sequence may be followed by a purge cycle to remove excess precursor and byproducts from the reaction chamber by exhausting the reaction chamber 102 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by: activating the precursor distribution system and the removal system to provide the second precursor, subsequently provide the first precursor, and subsequently provide the reactant. In some embodiments the program sequence of providing the second precursor, subsequently providing the first precursor, and subsequently providing the reactant may be repeated one or more times. In some embodiments each step in the program sequence may be followed by a purge cycle to remove excess precursor and byproducts from the reaction chamber by exhausting the reaction chamber 102 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by: activating the precursor distribution system and the removal system to provide the first precursor, subsequently provide the reactant, and subsequently provide the second precursor. In some embodiments the program sequence of providing the first precursor, subsequently providing the reactant, and subsequently providing the second precursor may be repeated one or more times. In some embodiments each step in the program sequence may be followed by a purge cycle to remove excess precursor and byproducts from the reaction chamber by exhausting the reaction chamber 102 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by: activating the precursor distribution system and the removal system to provide the reactant, subsequently provide the first precursor, subsequently provide the second precursor, and subsequently provide the reactant. In some embodiments the program sequence of providing the reactant, subsequently providing the first precursor, subsequently providing the second precursor, and subsequently providing the reactant may be repeated one or more times. In some embodiments each step in the program sequence may be followed by a purge cycle to remove excess precursor and byproducts from the reaction chamber by exhausting the reaction chamber 102 utilizing vacuum pump 138 and optionally flowing a purge gas from source vessel 116.

In some embodiments of the disclosure, the program in memory 144 may be programmed to execute infiltration of the infiltrateable material 106 when run on the sequence controller 142 by: activating the precursor distribution system and the removal system to provide the reactant, subsequently provide the first precursor, subsequently provide the reactant, and subsequently provide the second precursor. In some embodiments the program sequence of providing the reactant, subsequently providing the first precursor, subsequently providing the reactant, and subsequently providing the second precursor may be repeated one or more times. In some embodiments each step in the program sequence may be followed by a purge cycle to remove excess precursor and byproducts from the reaction chamber by exhausting the reaction chamber 102 utilizing vacuum pump 138 and optionally flowing a purge gas from source vessel 116.

The embodiments of the disclosure may also include methods for infiltrating an infiltrateable material and particular methods for infiltrating an infiltrateable material with silicon atoms.

Therefore the embodiments of the disclosure may provide a method of infiltrating an infiltrateable material, the method comprising: providing a substrate with the infiltrateable material disposed thereon in a reaction chamber; providing a first precursor comprising a silicon compound to the infiltrateable material in the reaction chamber for a first time period (T₁) whereby the infiltrateable material disposed on the substrate within the reaction chamber is infiltrated with silicon atoms; and purging the reaction chamber for a second time period (T₂).

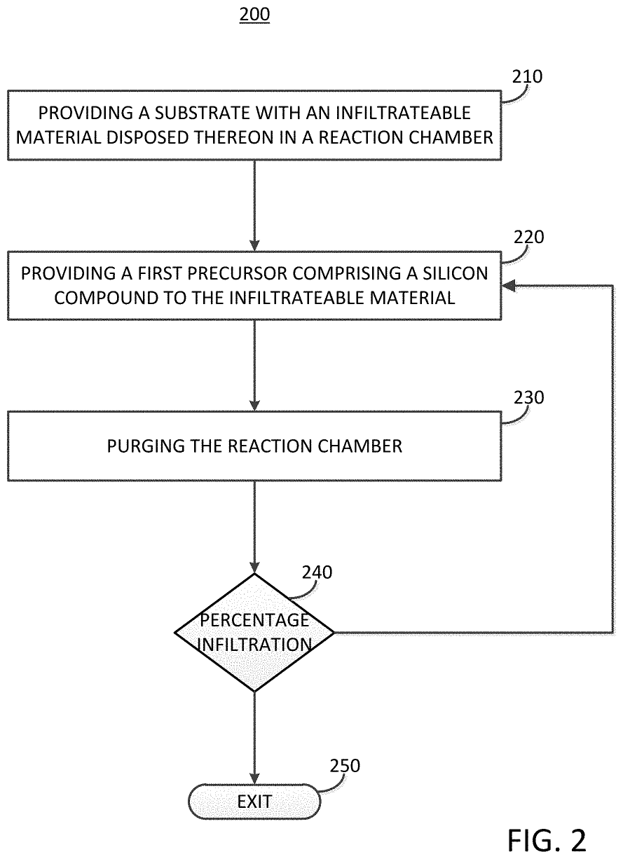

An exemplary infiltration process 200 is illustrated in FIG. 2, wherein the infiltration process 200 may proceed by means of a process block 210 comprising, providing a substrate with an infiltrateable material disposed thereon in a reaction chamber. The substrate may comprise one or more materials, as previously disclosed within, and may comprise a planar or patterned substrate. In some embodiments, the infiltrateable material comprises at least one of a photoresist, an extreme ultraviolet (EUV) resist, an immersion resist, a chemically amplified resist (CAR), an electron beam resist, a porous material, or a hardmask material, such as, for example, a silicon oxide, a silicon nitride, or a silicon oxynitride.

The exemplary infiltration process 200 may continue by means of a process block 220 comprising, providing a first precursor comprising a silicon compound to the infiltrateable material in the reaction chamber for a first time period (T₁) whereby the infiltrateable material disposed on the substrate within the reaction chamber is infiltrated with silicon atoms. The first precursor may comprise a vapor phase silicon compound and may include any of the silicon compounds previously described herein. In some embodiments, the first precursor comprises at least one of an aminosilane, an ethoxysilane, a methoxysilane, or a silicon halide. In some embodiments, the first precursor comprises at least one of 3-aminopropyl triethoxysilane (APTES), 3-aminopropyl triethoxysilane (APTES), or hexachlorodisilane (HCSD). In some embodiments, the first time period (T₁), i.e., the time period the first precursor is provided to and contacts the infiltrateable material, may be between approximately 25 milliseconds and approximately 10 hour.

The exemplary infiltration process 200 may continue by means of a process block 230 comprising, purging the reaction chamber for a time period (T₂). For example, the reaction chamber may be purged by exhausting excess first precursor (and any reaction byproducts) from the reaction chamber utilizing a vacuum pump. In addition, the purge process may also comprise supplying a purge gas into the reaction chamber to assist in the evacuation of excess precursor gas. In some embodiments, the reaction chamber may be purged for a time period (T₂) of between approximately 25 milliseconds and approximately 10 hours.

The exemplary infiltration process 200 may continue with a decision gate 240, wherein the decision gate 240 may be dependent on the atomic percentage (atomic-%) of silicon infiltrated into the infiltrateable material. If insufficient silicon atoms are infiltrated into the infiltrateable material then the exemplary process 200 may return to the process block 220 and the infiltrateable material may be again exposed to the first silicon precursor by providing the first silicon precursor to the infiltrateable material subsequently followed by the process block 230 wherein the reaction chamber is purged of excess precursor and byproducts. Therefore, some embodiments of disclosure may comprise repeating the steps of providing the first precursor and subsequently the step of purging the reaction chamber one of more times until a desired atomic-% of silicon atoms are infiltrated into the infiltrateable material. Once the desired atomic-% of silicon atoms are infiltrated into the infiltrateable material, the exemplary process may exit via a process block 250. For example, the exemplary infiltration process may produce an infiltrated infiltrateable material with an atomic-% of silicon atoms greater than 0.1%, or greater than 5%, or greater than 15%, or greater than 50%, or greater than 75%, or even approximately 100%. In some embodiments, the infiltration process may produce an infiltrated infiltrateable material with an atomic-% of silicon atoms greater than 15%. In some embodiments, the infiltrated silicon atoms may be homogeneously distributed within the infiltrateable material. In some embodiments, the infiltrated silicon atoms may be non-homogeneously distributed within the infiltrateable material.

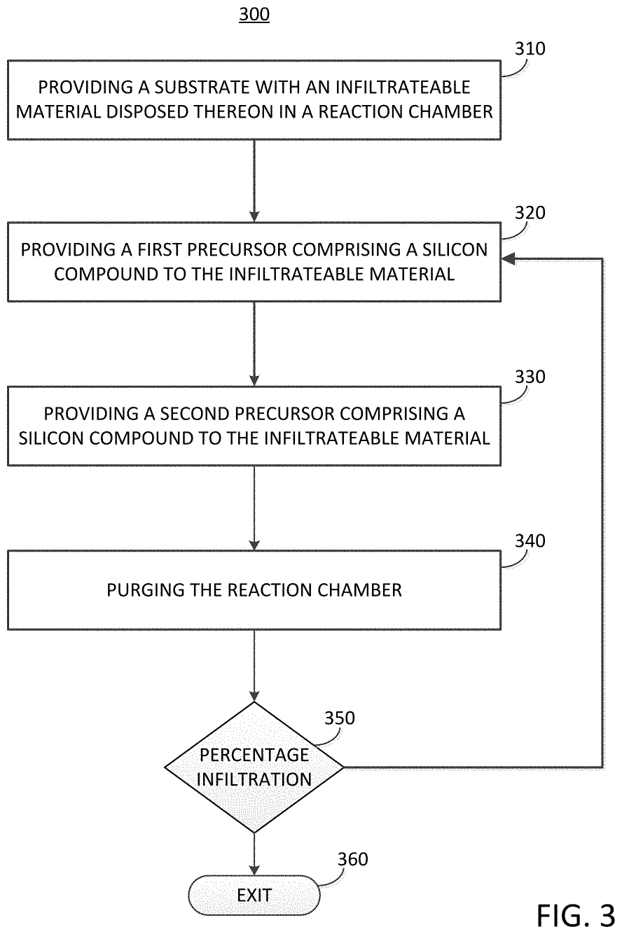

An additional exemplary infiltration process 300 may be illustrated with reference to FIG. 3, wherein the exemplary infiltration process 300 may proceed by means of a process block 310 comprising, providing a substrate with an infiltrateable material disposed thereon in a reaction chamber. The process block 310 is equivalent to process block 210 of FIG. 2 and is therefore not described in greater detail herein.

The exemplary infiltration process 300 may continue by means of a process block 320 comprising, providing a first precursor comprising a silicon compound to the infiltrateable material in the reaction chamber for a first time period (T₁) whereby the infiltrateable material disposed on the substrate within the reaction chamber is infiltrated with silicon atoms. The process block 320 is equivalent to process block 220 of FIG. 2 and is therefore not described in greater detail herein.

The exemplary infiltration process 300 may continue by means of a process block 330 comprising, providing a second precursor comprising a silicon compound to the infiltrateable material in the reaction chamber for a third time period (T₃) whereby the infiltrateable material disposed on the substrate within the reaction chamber is infiltrated with silicon atoms. For example, the third time period (T₃) for providing the second precursor and contacting the second precursor with the infiltrateable material may be between approximately 25 milliseconds and approximately 10 hours.

In some embodiments of the disclosure, the second precursor comprising a silicon compound may comprise any of the silicon compounds described in detail previously herein. In particular embodiments, the second precursor may comprise at least one of an aminosilane, an ethoxysilane, a methoxysilane, or a silicon halide. In some embodiments, the second precursor may comprise at least one of 3-aminopropyl triethoxysilane (APTES), 3-aminopropyl triethoxysilane (APTES), or hexachlorodisilane (HCSD).

In some embodiments of the disclosure, the first precursor may be different to the second precursors, i.e., the first precursor may comprise a first silicon vapor phase reactant and the second precursor may also comprise a second silicon vapor phase reactant which is different to the first silicon vapor phase reactant.

Although illustrated as two separate process blocks in FIG. 3, the process block 320 comprising providing a first precursor and the process block 330 comprising providing a second precursor may proceed simultaneously, i.e., the first precursor and the second precursor may be provided simultaneously to the infiltrateable material in the reaction chamber to thereby infiltrate the infiltrateable materials with silicon atoms.

In alternative embodiments, the first precursor and the second precursor may be separately provided to the infiltrateable material, i.e., such that the first precursor and the second precursor do not concurrently contact the infiltrateable material. In such embodiments, wherein the first precursor and the second precursor are separately provided to the infiltrateable material, the exemplary infiltration process may further comprise, a reaction chamber purge between providing the first precursor and providing the second precursor, such that excess first precursor (and any reaction byproducts) may be removed from the reaction chamber prior to providing the second precursor to the infiltrateable material. An additional reaction chamber purge may be performed after providing the second precursor to remove excess second precursor and any reaction byproducts. It should be noted that in such embodiments wherein the first precursor and the second precursor are provided separately to the infiltrateable material, the sequence of the providing of the precursors may be such that the second precursor is initially provided to the infiltrateable material followed subsequently by the first precursor, with an optional reaction chamber purge between the providing steps.

The exemplary infiltration process 300 may proceed by means of a process block 340 comprising, purging the reaction chamber for a fourth time period (T₄) after providing the second precursor to the infiltrateable material. For example, the fourth time period (T₄) utilized to remove excess precursor(s) from the reaction chamber may be between approximately 25 milliseconds and approximately 10 hours.

The exemplary infiltration process 300 may continue with a decision gate 350, wherein the decision gate 350 may be dependent on the atomic percentage (atomic-%) of silicon infiltrated into the infiltrateable material. If insufficient silicon atoms are infiltrated into the infiltrateable material then the exemplary process 300 may return to the process block 320 and the infiltrateable material may be again exposed to the first silicon precursor (process block 320) and the second precursor (process block 330) (with optional intervening reaction chamber purge) subsequently followed by the process block 340 wherein the reaction chamber is purged of excess precursor and any reaction byproducts. Therefore, the methods disclosure herein may comprise repeating the steps of providing the first precursor, subsequently purging the reaction chamber, subsequently providing the second precursor, and subsequently purging the reaction chamber one or more times, i.e., until a desired atomic-% of silicon is infiltrated into the infiltrateable material.

Once the desired atomic-% of silicon atoms are infiltrated into the infiltrateable material, the exemplary process 300 may exit via a process block 360.

Not to be bound by any particularly theory but it is believe that the methods of the disclosure that comprise providing a first silicon precursor and a second different silicon precursor to the infiltrateable material may result in the infiltration of a greater atomic-% of silicon atoms. For example, the exemplary infiltration process 300 may produce an infiltrated infiltrateable material with an atomic-% of silicon atoms greater than 0.1%, or greater than 5%, or greater than 15%, or greater than 50%, or greater than 75%, or even approximately 100%. In some embodiments, the infiltration process may produce an infiltrated infiltrateable material with an atomic-% of silicon atoms greater than 15%. In some embodiments, the infiltrated silicon atoms may be homogeneously distributed within the infiltrateable material. In some embodiments, the infiltrated silicon atoms may be non-homogeneously distributed within the infiltrateable material.

In additional embodiments of the disclosure, the methods disclosed may comprise sequential synthesis infiltration (SIS) methods which may comprise, alternately, exposing an infiltrateable material to two more precursors to enable the infiltration of atoms and/or materials into the infiltrateable material, such as, for example, a polymer resist or hardmask material.

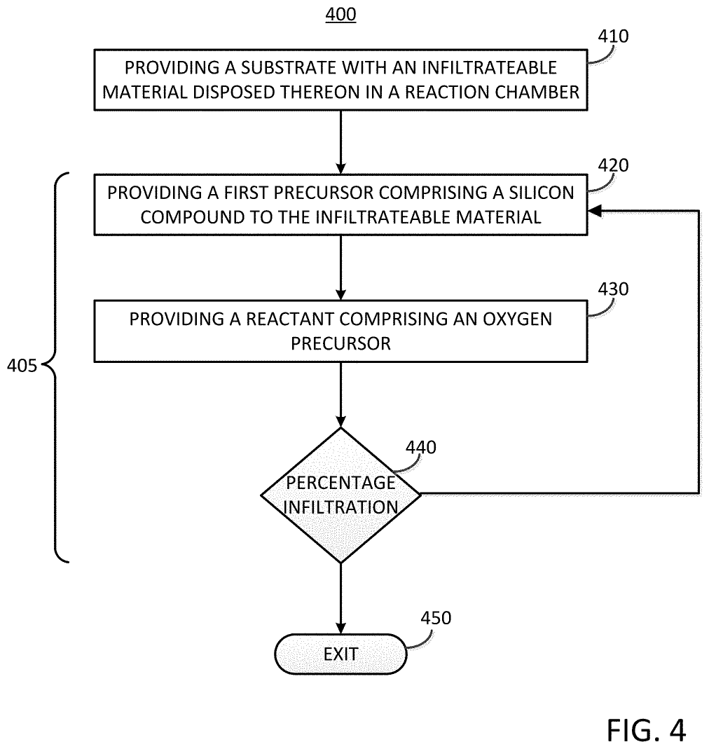

Therefore, additional embodiments of the disclosure may be illustrated with reference to FIG. 4 which illustrates exemplary SIS process 400. In greater detail, the exemplary SIS process may commence by means of a process block 410 comprising, providing a substrate with an infiltrateable material disposed thereon in a reaction chamber. Process block 410 is equivalent to process 210 of FIG. 2 and is therefore not described in greater detail herein.

The exemplary SIS process 400 may proceed by performing one or more SIS cycles 405 wherein a SIS cycle may proceed by means of a process block 420 comprising, providing a first precursor comprising a silicon compound to the infiltrateable material in the reaction chamber for a first time period (T₁) whereby the infiltrateable material disposed on the substrate within the reaction chamber is infiltrated with silicon atoms. Process block 420 is equivalent to process block 220 of FIG. 2 and is therefore not described in greater detail herein.

The SIS cycle 405 of exemplary SIS process 400 may proceed by means of a process block 430 comprising, providing a reactant comprising an oxygen precursor to the infiltrateable material in the reaction chamber for a fifth time period (T₅) whereby the infiltrateable material disposed on the substrate within the reaction chamber is infiltrated with oxygen atoms.

In more detail, in some embodiments the reactant comprising an oxygen precursor and may comprise a vapor of least one or water (H₂O), or hydrogen peroxide (H₂O₂). In some embodiments, the oxygen precursor may comprise ozone (O₃), or molecular oxygen (O₂). In some embodiments of the disclosure, the reactant comprising an oxygen precursor may comprise an oxygen based plasma comprising oxygen atoms, oxygen ions, oxygen radicals, and excited species of oxygen produced by the plasma excitation of an oxygen containing gas, such as, for example, at least one of ozone (O₃), or molecular oxygen (O₂). For example, in some embodiments the methods may comprise providing the reactant comprising an oxygen precursor to the infiltrateable material for a fifth time period (T₅) between approximately 25 milliseconds and approximately 10 hours.

In some embodiments of the disclosure, the process block 420 of providing a first precursor and the process block 430 of providing a reactant may be separated by a reaction chamber purge to remove excess precursor and reaction byproducts from the reaction chamber. In addition, the process block 430 of providing a reactant may be followed by an additional reaction chamber purge to remove excess reactant and reaction byproducts. It should also be noted that the sequence of processes illustrated in FIG. 4 may be altered such that the reactant comprising an oxygen precursor may be initial provided to the infiltrateable material followed subsequently by providing the first precursor to the infiltrateable material.

The SIS cycle 405 of exemplary SIS process 400 may continue with a decision gate 440, wherein the decision gate 440 may be dependent on the atomic percentage (atomic-%) of silicon infiltrated into the infiltrateable material and the atomic percentage (atomic-%) of oxygen infiltrated into the infiltrateable material. If insufficient silicon atoms and oxygen atoms are infiltrated into the infiltrateable material then the SIS cycle 405 of exemplary SIS process 400 may be repeated by returning to the process block 420 and the infiltrateable material may again be exposed to the first silicon precursor (process block 420) and the reactant comprising an oxygen precursor (process block 430), with optional reaction chamber purges after each individual process block.

Therefore, in some embodiments, a unit SIS cycle 405 of exemplary SIS process 400 may comprise providing a first precursor comprising a silicon compound, purging the reaction chamber, providing a reactant comprising an oxygen precursor, and purging the reaction chamber. In alternative embodiments, a unit SIS cycle 405 of exemplary SIS process 400 may comprise providing a reactant comprising an oxygen precursor, purging the reaction chamber, providing a first precursor comprising a silicon compound, and purging the reaction chamber.

Once a desired atomic-% of silicon atoms and oxygen atoms have been infiltrated into the infiltrateable material the exemplary SIS process 400 may exit via a process block 450.

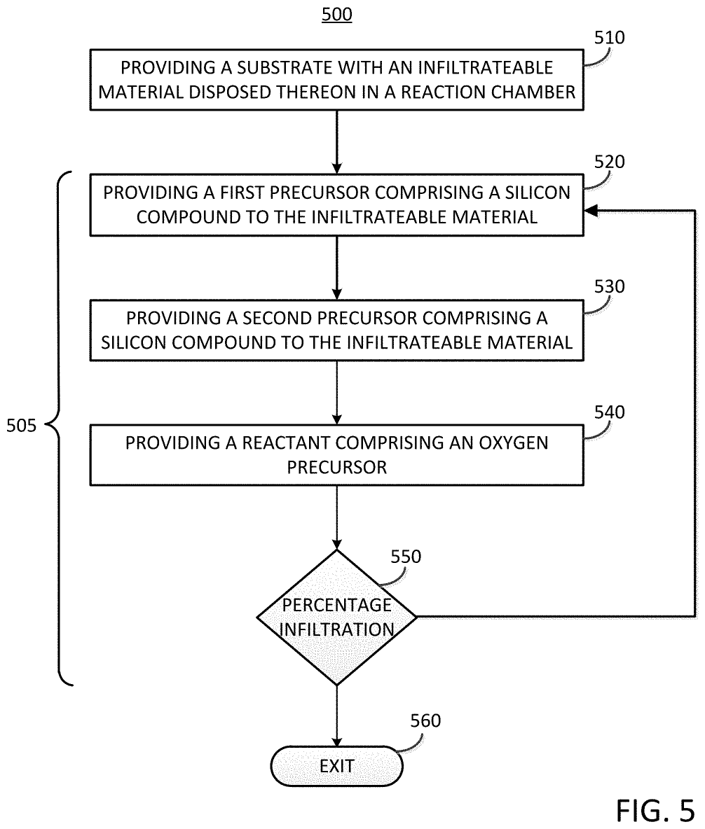

Additional embodiments of the disclosure may comprise further sequential synthesis infiltration (SIS) methods which may be illustrated with reference to FIG. 5 which illustrates exemplary SIS process 500. In greater detail, the exemplary SIS process 500 may commence by means of a process block 510 comprising, providing a substrate with an infiltrateable material disposed thereon in a reaction chamber. Process block 510 is equivalent to process 210 of FIG. 2 and is therefore not described in greater detail herein.

The exemplary SIS process 500 may proceed with a SIS cycle 505 which may start by means of a process block 520 comprising, providing a first precursor comprising a silicon compound to the infiltrateable material in the reaction chamber for a first time period (T₁) whereby the infiltrateable material disposed on the substrate within the reaction chamber is infiltrated with silicon atoms. Process block 520 is equivalent to process block 220 of FIG. 2 and is therefore not described in greater detail herein.

The SIS cycle 505 of exemplary SIS process 500 may continue by means of a process block 530 comprising, providing a second precursor comprising a silicon compound to the infiltrateable material, wherein the second precursor is different from the first precursor. Process block 530 is equivalent to process block 330 of FIG. 3 and is therefore not described in greater herein.

The SIS cycle 505 of exemplary SIS process 500 may continue by means of a process block 540 comprising, providing a reactant comprising an oxygen precursor to the infiltrateable material. Process block 540 is equivalent to process block 430 of FIG. 4 and is therefore not described in greater detail herein.

The SIS cycle 505 of exemplary SIS process 500 may continue with a decision gate 550, wherein the decision gate 550 may be dependent on the atomic percentage (atomic-%) of silicon infiltrated into the infiltrateable material and the atomic percentage (atomic-%) of oxygen infiltrated into the infiltrateable material. If insufficient silicon atoms and oxygen atoms are infiltrated into the infiltrateable material then the SIS cycle 505 may be repeated by returning to the process block 520 and the infiltrateable material may again be exposed to the first silicon precursor (process block 520), and exposed to the second silicon precursor (process block 530), and exposed to the reactant comprising an oxygen precursor (process block 540). Once a desired atomic-% of silicon atoms and oxygen atoms have been infiltrated into the infiltrateable material the exemplary SIS process 500 may exit via a process block 560.

Therefore, the methods disclosed herein may comprise performing one or more sequential infiltration synthesis (SIS) cycles 505, wherein a unit SIS cycle may comprise: providing the first precursor comprising a silicon compound to the infiltrateable material; providing the second precursor comprising a silicon compound different from the first precursor, and providing the reactant comprising the oxygen precursor to the infiltrateable material.

In some embodiments, each step of a SIS cycle may be subsequently followed by a reaction chamber purge to remove excess precursor/reactive species in between successive process steps. An a non-limiting example, an exemplary unit SIS cycle may comprise, providing a first precursor, purging the reaction chamber, providing a second precursor, purging the reaction chamber, providing the reactant comprising the oxygen precursor, and purging the reaction chamber, wherein the SIS cycle may be repeated one or more times.

In some embodiments of the disclosure, the sequence of processes comprising a unit SIS cycle, of exemplary SIS process 500, may be performed in an alternative order. In some embodiments, a unit SIS cycle may comprise, providing a second precursor, purging the reaction chamber, providing the first precursor, purging the reaction chamber, providing the reactant comprising the oxygen precursor, and purging the reaction chamber, whereby the SIS cycle may be repeated one or more times. In some embodiments, a unit SIS cycle may comprise, providing a first precursor, purging the reaction chamber, providing the reactant, purging the reaction chamber, providing a second precursor, and purging the reaction chamber. In some embodiments, a unit SIS cycle may comprise, providing a first precursor, purging the reaction chamber, providing the reactant, purging the reaction chamber, providing a second precursor, purging the reaction chamber, providing a reactant, and purging the reaction chamber. In some embodiments, a unit SIS cycle may comprise, providing a reactant, purging the reaction chamber, providing a first precursor, purging the reaction chamber, providing a second precursor, purging the reaction chamber, providing a reactant, and purging the reaction chamber. In some embodiments, a unit SIS cycle may comprise, providing a reactant, purging the reaction chamber, providing a first precursor, purging the reaction chamber, providing a reactant, purging the reaction chamber, and providing a second precursor, and purging the reaction chamber.

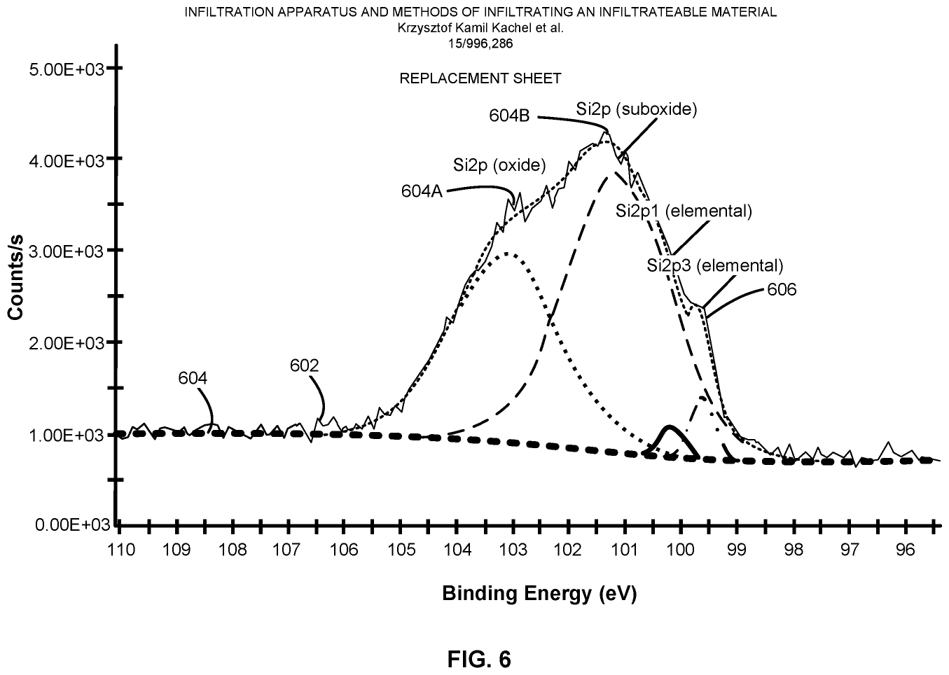

As a non-limiting example illustrating the capabilities of the infiltration apparatus and infiltration methods disclosed herein, FIG. 6 illustrates a x-ray photoelectron spectrum (XPS) obtained from an extreme ultraviolet (EUV) chemically amplified resist infiltrated with silicon atoms utilizing the infiltration apparatus and infiltration processes disclosed herein. In more detail, the EUV chemically amplified resist was infiltrated using a silicon precursor comprising hexachlorodisilane (HCDS). Examination of the XPS spectrum 600 demonstrates the raw data line 602 and the processed data line 604 wherein processed data line 604 indicates a number of significant features. For example, the shoulder in the data labelled as 604A and the peak labelled as 604B both indicate the present of a silicon oxide in the infiltrated EUV resist, whereas the peak labelled as 606 indicates the present of elemental silicon in the infiltrated EUV resist. Therefore, the embodiments of the disclosure may not only infiltrate silicon atoms into the infiltrateable material but may, in some embodiments, infiltrate the infiltrateable material with a silicon oxide. In the example illustrated in FIG. 6, the EUV resist is infiltrated with silicon atoms to a concentration of approximately 6 atomic-%.

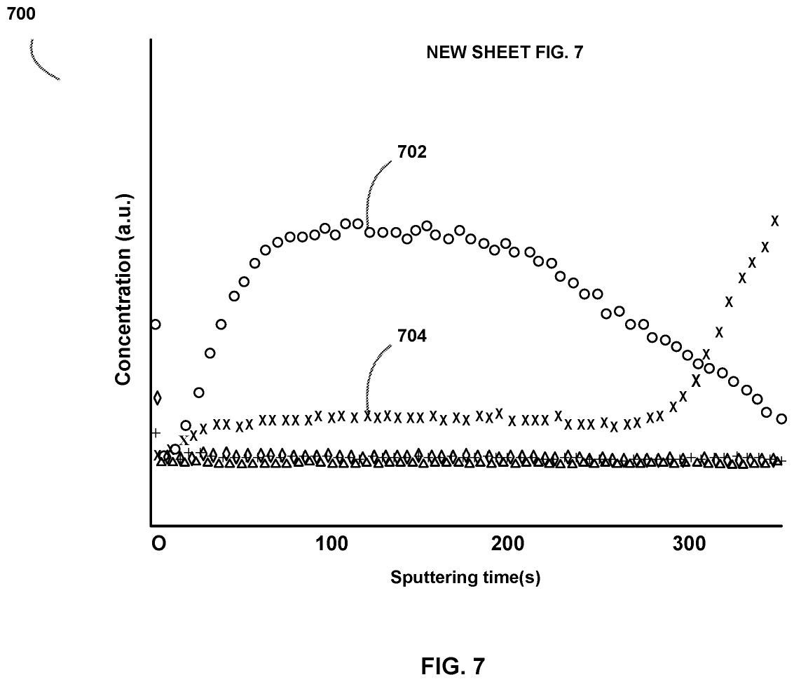

As a further non-limiting example illustrating the capabilities of the infiltration apparatus and infiltration methods disclosed herein, FIG. 7 illustrates a secondary ion mass spectrum (SIMS) 700 obtained from an EUV chemically amplified resist film infiltrated with silicon atoms utilizing the infiltration apparatus and infiltration processes described herein. In more detail, the EUV chemically amplified resist film was infiltrated using a silicon precursor comprising 3-aminopropyl triethoxysilane (APTES). Examination of the SIMS spectrum 700 obtained from the infiltrated EUV resist film demonstrates a data line 702 indicating the carbon (C) component in the film, which corresponds to the organic EUV resist, and data line 704 indicates the silicon (Si) component in the film, which corresponds to the plurality of silicon atoms infiltrated into the EUV resist. The data line 704 representing the silicon component in the EUV resist film indicates that the silicon atoms are homogeneous distributed throughout the EUV resist film. In this particular example, the EUV is infiltrated with silicon atoms to a concentration of approximately 3 atomic-%.

The infiltration apparatus and infiltration methods disclosed herein may be employed for formation of infiltrated materials, such as polymer resists and hardmask materials, with an increase resistance to etch processes. The infiltrated materials may be utilized in the fabrication of semiconductor device structures, such as, for example, by being employed as an etch mask for the transfer of patterned infiltrated features into an underlying substrate.

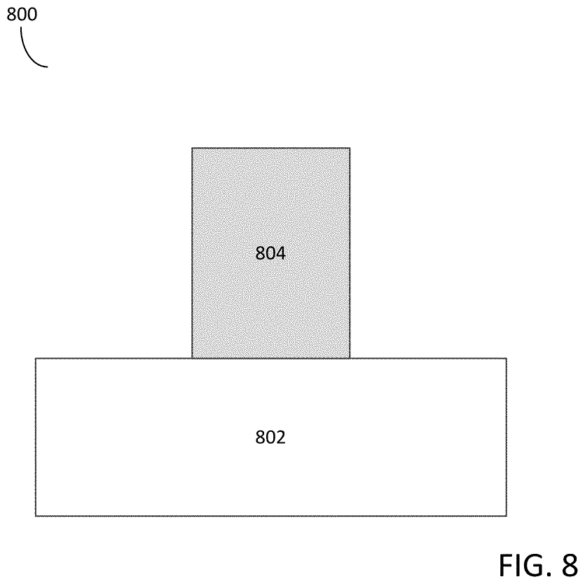

As a non-limiting example of the embodiments of the disclosure, FIG. 8 illustrates a semiconductor device structure 800 including a substrate 802 and an infiltrated polymer resist feature 804. In more detail, the substrate 802 may include any of the materials previously described with respect to substrate 104 of FIG. 1 and may further comprise a planar structure (as illustrated in FIG. 8), or a non-planar structure. In some embodiments, the substrate 802 may include fabricated, or at least partially fabricated, semiconductor device structures, such as, for example, transistors and/or memory elements.

In some embodiments of the disclosure, an infiltrated polymer resist feature 804 may be disposed over a surface of the substrate 802. For example, a polymer resist feature may be fabricated by standard photolithographic methods and may include any geometry or feature that may be feasible produced utilizing standard photolithographic methods, such features including, but not limited to, line features, block features, open pore features, and circular features. In some embodiments, the infiltrated polymer resist 804 may comprise, an organic component, and an inorganic component comprising a plurality of silicon (Si) atoms infiltrated within the organic component. In some embodiments, the concentration of the plurality of silicon atoms within the organic component may be greater than 0.1 atomic-%, or greater than 5 atomic-%, or greater than 15 atomic-%, or greater than 50 atomic-%, or greater than 75 atomic-%, or even approximately 100 atomic-%. In some embodiments, the concentration of the plurality of silicon atoms with the organic component may be greater than approximately 15 atomic-%.

In some embodiments, the plurality of silicon atoms infiltrated within the organic component may be distributed homogeneously throughout the organic component. In some embodiments, the plurality of silicon atoms infiltrated within the organic component may be distributed non-homogeneously throughout the organic component.

In some embodiments of the disclosure the organic component further comprises, a plurality of oxygen atoms infiltrated into the organic component. For example, the concentration of the plurality of oxygen atoms within the organic component may be greater than 0.1 atomic-%, or greater than 5 atomic-%, or greater than 15 atomic-%, or even greater than 50 atomic-%.

In some embodiments of the disclosure the organic component of the infiltrated polymer resist may further comprise a plurality of silicon atoms and a plurality of oxygen atoms. In some embodiments, the organic component of the infiltrated polymer resist may further comprise an infiltrated silicon oxide (SiₓO_{y}), wherein the silicon oxide is not limited to any specific stoichiometry. For example, the plurality of silicon atoms may be disposed within the organic component of infiltrated polymer resist 804 as elemental silicon (Si) and as a silicon oxide (SiₓO_{y}).

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

1. An infiltration apparatus comprising:
a reaction chamber constructed and arranged to hold at least a substrate provided with an infiltrateable material thereon;
a first precursor source constructed and arranged to provide a vapor of a first precursor comprising a silicon compound;
a precursor distribution system and removal system constructed and arranged to provide the reaction chamber with the vapor of the first precursor from the first precursor source and to remove the vapor of the first precursor from the reaction chamber; and
a sequence controller operably connected to the precursor distribution system and removal system and comprising a memory provided with a program to execute infiltration of the infiltrateable material when run on the sequence controller by;
activating the precursor distribution system and removal system to provide the vapor of the first precursor to the infiltrateable material on the substrate in the reaction chamber whereby the infiltrateable material on the substrate in the reaction chamber is infiltrated with silicon atoms by the reaction of the vapor of the first precursor with the infiltrateable material.

2. The apparatus according to claim 1, wherein the first precursor source is constructed and arranged to provide a vapor of a substituted silane.

3. The apparatus according to claim 2, wherein the first precursor source is constructed and arranged to provide a vapor of an aminosilane.

4. The apparatus according to claim 1, wherein the first precursor source is constructed and arranged to provide a vapor of a 3-aminopropyl and silicon comprising compound.

5. The apparatus according to claim 1, wherein the first precursor source is constructed and arranged to provide a vapor of a silicon precursor comprising an alkoxide ligand and an additional ligand other than an alkoxide ligand.

6. The apparatus according to claim 1, wherein the first precursor source is constructed and arranged to provide a vapor of 3-aminopropyl triethoxysilane (APTES).

7. The apparatus according to claim 1, wherein the first precursor source is constructed and arranged to provide a vapor of a silicon precursor comprising an amino-substituted alkyl group attached to a silicon atom.

8. The apparatus according to claim 1, wherein the first precursor source is constructed and arranged to provide a vapor of 3-aminopropyl-trimethoxysilane (APTMS).

9. The apparatus according to claim 1, wherein the first precursor source is constructed and arranged to provide a vapor of a silicon compound comprising a halide.

10. The apparatus according to claim 9, wherein the first precursor source is constructed and arranged to provide a vapor of a silicon halide, a halogenated silane, or a silane comprising halide.

11. The apparatus of claim 9, wherein the silicon compound comprises a chloride.

12. The apparatus according to claim 11, wherein the first precursor source is constructed and arranged to provide a vapor of at least one of hexachlorodisilane (HCDS), dichlorosilane (DCS), or silicon tetrachloride (SiCl₄).

13. The apparatus according to claim 1, wherein the apparatus comprises a second precursor source constructed and arranged to provide a vapor of a second precursor comprising a silicon compound; and the precursor distribution system and removal system is constructed and arranged to provide the reaction chamber with the vapor of the second precursor from the second precursor source and the program in the memory is programmed to execute infiltration of the infiltrateable material when run on the sequence controller by; activating the precursor distribution system and removal system to provide the vapor of the second precursor to the reaction chamber whereby the infiltrateable material on the substrate within the reaction chamber is infiltrated with silicon atoms from the vapor of the second precursor.

14. The apparatus according to claim 13, wherein the second precursor source is constructed and arranged to provide a vapor of a different silicon compound than the first precursor.

15. The apparatus according to claim 13, wherein the program in the memory is programmed to execute infiltration of the infiltrateable material when run on the sequence controller by; activating the precursor distribution system and the removal system to provide the second precursor simultaneously with the first precursor.

16. The apparatus according to claim 13, wherein the program in the memory is programmed to execute infiltration of the infiltrateable material when run on the sequence controller by; activating the precursor distribution system and removal system to provide the second precursor after the first precursor.

17. The apparatus according to claim 1, wherein the apparatus is a sequential infiltration synthesis apparatus further comprising:
a reactant source vessel and a reactant supply line constructed and arranged to provide a reactant comprising an oxygen precursor to the reaction chamber, wherein the program in the memory of the sequence controller is programmed to execute infiltration of the infiltrateable material when run on the sequence controller by activating the precursor distribution system and the removal system to remove gas from the reaction chamber; and activating the precursor distribution system and removal system to provide the reactant comprising an oxygen precursor to the reaction chamber whereby the infiltrateable material on the substrate in the reaction chamber is infiltrated with silicon atoms and oxygen atoms by the reaction of the first precursor and the reactant comprising an oxygen precursor with the infiltrateable material.

18. The apparatus according to claim 17, wherein the reactant source vessel further comprises a reactant evaporator constructed and arranged to evaporate at least one of water (H₂O), or hydrogen peroxide (H₂O₂).

19. The apparatus according to claim 17, wherein the reactant source vessel contains a gaseous oxygen precursor including at least one of ozone (O₃), and molecular oxygen (O₂).

20. The apparatus according to claim 17, wherein the apparatus further comprises a plasma generator constructed and arranged to generate a plasma from the oxygen precursor thereby providing one or more of atomic oxygen, oxygen radicals, and excited species of oxygen to the reaction chamber.

21. The apparatus according to claim 17, wherein the apparatus comprises a second precursor source constructed and arranged to evaporate a vapor of a second precursor comprising a silicon compound; and the precursor distribution system and removal system is constructed and arranged to provide the reaction chamber with the vapor of the second precursor from the second precursor source and the program in the memory is programmed to execute infiltration of the infiltrateable material when run on the sequence controller by; activating the precursor distribution system and the removal system to provide the vapor of the second precursor.

22. The apparatus according to claim 21, wherein the program in the memory is programmed to execute infiltration of the infiltrateable material when run on the sequence controller by: activating the precursor distribution system and the removal system to provide the first precursor, subsequently the reactant, subsequently the second precursor, and subsequently the reactant.

23. The apparatus according to claim 21, wherein the program in the memory is programmed to execute infiltration of the infiltrateable material when run on the sequence controller by: activating the precursor distribution system and removal system to repeat providing the first precursor, subsequently the reactant, subsequently the second precursor, and subsequently the reactant for multiple times.

24. The apparatus according to claim 21, wherein the program in the memory is programmed to execute infiltration of the infiltrateable material when run on the sequence controller by: activating the precursor distribution system and the removal system to remove the precursor and/or reactants from the reaction chamber in between each step of providing the first precursor, subsequently the reactant, subsequently the second precursor, and subsequently the reactant.

25-56. (canceled)
